(19) United States
(12) Patent Application Publication
(10) Pub. No.: US 2019/0123196 A1
(43) Pub. Date: Apr. 25, 2019

(54) Trench-Type Field Effect Transistor (Trench FET) With Improved Poly Gate Contact

(71) Applicant: Microchip Technology Incorporated, Chandler, AZ (US)

(72) Inventor: Greg Dix, Tempe, AZ (US)

(73) Assignee: Microchip Technology Incorporated, Chandler, AZ (US)

(21) Appl. No.: 16/044,883

(22) Filed: Jul. 25, 2018

Related U.S. Application Data
(60) Provisional application No. 62/576,999, filed on Oct. 25, 2017.

(51) Int. Cl. H01L 29/78; H01L 29/08; H01L 29/423; H01L 29/10; H01L 29/66; H01L 27/088; H01L 21/321

(52) U.S. Cl. CPC H01L 29/7827; H01L 29/0847; H01L 29/4236; H01L 21/3212; H01L 29/66666; H01L 27/088; H01L 29/1087

(57) ABSTRACT

An integrated circuit (IC) device may include a plurality of trench-type field-effect transistors (trench FETs). Each trench FET may include a poly gate trench formed in an epitaxy region, a poly gate formed in the poly gate trench, a front-side poly gate contact, and a lateral gate coupling element (e.g., a lateral “strap”) extending over or adjacent, and in contact with, at least one surface of the poly gate formed in the trench and electrically connecting the poly gate to the front-side poly gate contact. The lateral gate coupling element may be formed from a material having a higher electrical conductivity than the poly gate, e.g., tungsten or other metal. The lateral gate coupling element may be at least partially located in the poly gate trench.

### RELATED APPLICATION

This application claims priority to U.S. Provisional Patent Application No. 62/576,999 filed Oct. 25, 2017, the entire contents of which are hereby incorporated by reference for all purposes.

### TECHNICAL FIELD

The present disclosure relates to semiconductor devices, e.g., field-effect transistors (FETs) and, more particularly, to trench FETs or other trench-type semiconductor devices having front-side source and gate contacts.

### BACKGROUND

Trench-based transistors used in integrated circuits (ICs) include field-effect transistors (FETs) such as power MOSFETs. Transistors formed using trenches may include gate electrodes that are buried in a trench etched in the silicon. This may result in a vertical channel. In many such FETs, the current may flow from front side of the semiconductor die to the back side of the semiconductor die. Transistors formed using trenches may be considered vertical transistors, as opposed to lateral devices. Trench FET devices may allow better density through use of the trench feature, as compared with lateral FETs.

FIGS. 1A-1O illustrate a conventional method for forming an IC structure including multiple trench FET structures, including steps for forming poly gate contacts conductively coupled to the poly gates of each trench FET.

FIGS. 1A-1C show an example technique for forming a plurality of poly gate trenches. As shown in FIG. 1A, a lightly-doped epitaxy (EPI) layer 12 may be formed over a highly-doped bulk silicon substrate 10, and a transition region 14 may form between the EPI layer 12 and bulk substrate 10. The transition region 14 may define a transition from the more lightly doped EPI layer 12 to the more heavily doped bulk substrate region 10. The more lightly doped region may be light enough to survive a breakdown field. The resistance of this region may have consequences for operation of the FET because this area is typically not a pure metal.

Body and source regions 20 may be formed in the EPI 12 by suitable dopant implants, as known in the art. An oxide or insulation layer 22 may be formed, e.g., grown, on the EPI layer 12, and a nitride layer 24 may be deposited over the oxide layer 22.

As shown in FIG. 1B, a mask 30 (e.g., photoresist) may be formed and patterned to define trenches 32 in the mask 30.

As shown in FIG. 1C, at least one etch may be performed through the mask trenches 32 to remove portions of the nitride layer 24, oxide layer 22, and EPI region 12, to define a plurality of poly gate trenches 34.

As shown in FIG. 1D, the mask 30 may be removed (e.g., stripped), and an oxide 40 may be deposited over the structure.

As shown in FIG. 1E, a chemical mechanical planarization (CMP) process may be performed to remove the oxide 40 deposited on the nitride layer 24.

As shown in FIG. 1F, the nitride layer may be removed, e.g., stripped.

As shown in FIG. 1G, a gate oxide 44 may be grown on the exposed sidewall surfaces in the poly gate trenches 34.

As shown in FIG. 1H, a poly layer 50 may be deposited over the structure and extending into the poly gate trenches 34. The poly layer 50 may be doped, e.g., as known in the art.

Each of FIGS. 1I through 1O includes (a) an example first cross-sectional view (left side) corresponding with a first region of the device structure, e.g., at a laterally interior area of the structure, and (b) an example second cross-sectional view (right side) corresponding with a second region of the device structure where a top-side gate contact is provided, e.g., at or near a perimeter or lateral edge of the structure or at any other location selected for gate contact. The example second cross-sectional view shown in the right side of each FIG. 1I-1O could represent a 90 degree rotated view of the left-side view, e.g., a cross-section taken through one of the poly gate trenches 34, or could represent a co-planar or parallel plane view as the example left-side, e.g., at a different location in the device (e.g., at a perimeter or edge region of the device).

As shown in FIG. 1I (right side view), a photomask 56 may be formed over the poly material 50 in each gate poly trench 34 and patterned as shown.

As shown in FIG. 1J, an etch may be performed to remove portions of the poly gate material 50 and thereby define a discrete poly gate 60 in each respective poly gate trench 34 (left side view), and to define a lateral extension 62 of the poly gate material (right side view) that is subsequently connected to a poly gate contact, as discussed below.

As shown in FIG. 1K (left and right side views), remaining portions of the photomask 56 may be removed and an oxide layer 66 may be deposited over the structure.

As shown in FIG. 1L (left and right side views), a photomask 70 may be formed and patterned as shown, to define openings for forming source contact trenches and poly gate contact trenches.

As shown in FIG. 1M (left and right side views), at least one etch may be performed through the patterned openings in the photomask and through any underlying oxide or insulation layer(s) (e.g., layer 22) to form (a) source contact trenches 72 that expose areas of the top surface of the EPI layer 12, as shown in the left side view, and (b) poly gate contact trenches 74 that expose a top surface of respective poly gate material extensions 62, as shown in the right side view.

As shown in FIG. 1N, a conductive material 80, e.g., tungsten or other metal, may be deposited over the structure and extending into the source contact trenches 72 and poly gate contact trenches 74 (e.g., using a tungsten plug process).

As shown in FIG. 1O, a CMP process may be performed to remove upper portions of the conductive material 80, e.g., tungsten, and thereby define (a) a plurality of discrete source contacts 82, each contacting a doped source region in the EPI 12, indicated at 90 (left side view), and (b) a plurality of poly gate contacts 84, each contacting a respective poly gate material extension 62 (right side view).

### SUMMARY

Some embodiments of the present disclosure provide a trench FET structure including a lateral gate coupling element, e.g., a “strap” formed from metal (e.g., tungsten) or other electrically conductive material and extending laterally over or adjacent the poly gate and coupled to a front-side poly gate contact. Some embodiments include an integrated circuit (IC) structure including a plurality of such trench FETs.

One embodiment provides an IC device may include a plurality of trench FETs. Each trench FET may include a poly gate trench formed in an epitaxy region, a poly gate formed in the poly gate trench, a front-side poly gate contact, and a lateral gate coupling element (e.g., a lateral “strap”) extending over or adjacent at least one surface of the poly gate formed in the trench and electrically connecting the poly gate to the front-side poly gate contact.

In some embodiments, the lateral gate coupling element may be formed from a material having a higher electrical conductivity than the poly gate. For example, the lateral gate coupling element may be formed from tungsten or other metal.

In some embodiments, the lateral gate coupling element may be at least partially located in the poly gate trench.

Another embodiment provides a method of forming an integrated circuit (IC) structure including a plurality of trench-type field-effect transistors (trench FETs). The method may include forming a poly gate trench in an epitaxy region, forming a poly gate in the poly gate trench, forming a lateral gate coupling element extending over or adjacent and coupled to at least one surface of the poly gate, and forming a front-side poly gate contact coupled to the lateral gate coupling element, wherein the lateral gate coupling element forms an electrical connection between the poly gate and the front-side poly gate contact.

In one embodiment, the method includes etching a top portion of the poly gate in the poly gate trench to define a recess in the poly gate, and forming the lateral gate coupling element such that the lateral gate coupling element extends at least partially into the etched recess in the poly gate.

### BRIEF DESCRIPTION OF THE FIGURES

Example aspects and embodiments are discussed below with reference to the drawings, in which:

FIGS. 1A-1O illustrate a conventional process for forming an integrated circuit structure including trench FET structures, including steps for forming poly gate contacts conductively coupled to the poly gates of each trench FET;

FIGS. 2A-2P illustrate an example process for forming an integrated circuit structure including trench FET structures, including steps for forming poly gate contacts and a lateral gate coupling element, e.g., a “strap” conductively connecting each poly gate to a respective gate contact, according to one embodiment of the present invention; and

FIGS. 3A-3M illustrate another example process for forming an integrated circuit structure including trench FET structures, including steps for forming poly gate contacts and a lateral gate coupling element conductively connecting each poly gate to a respective gate contact, according to one embodiment of the present invention.

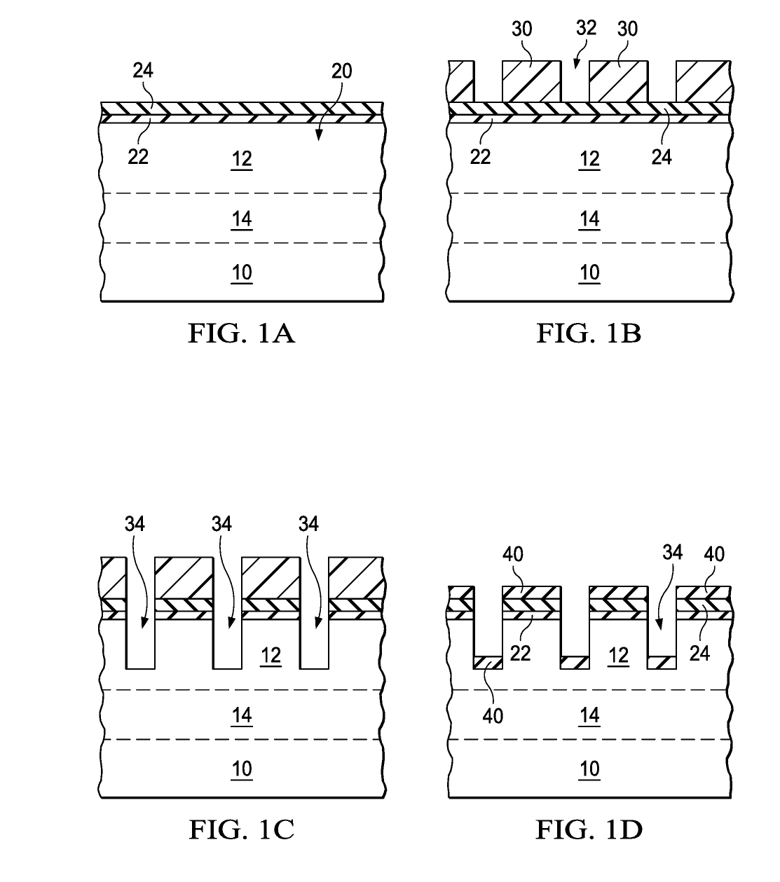

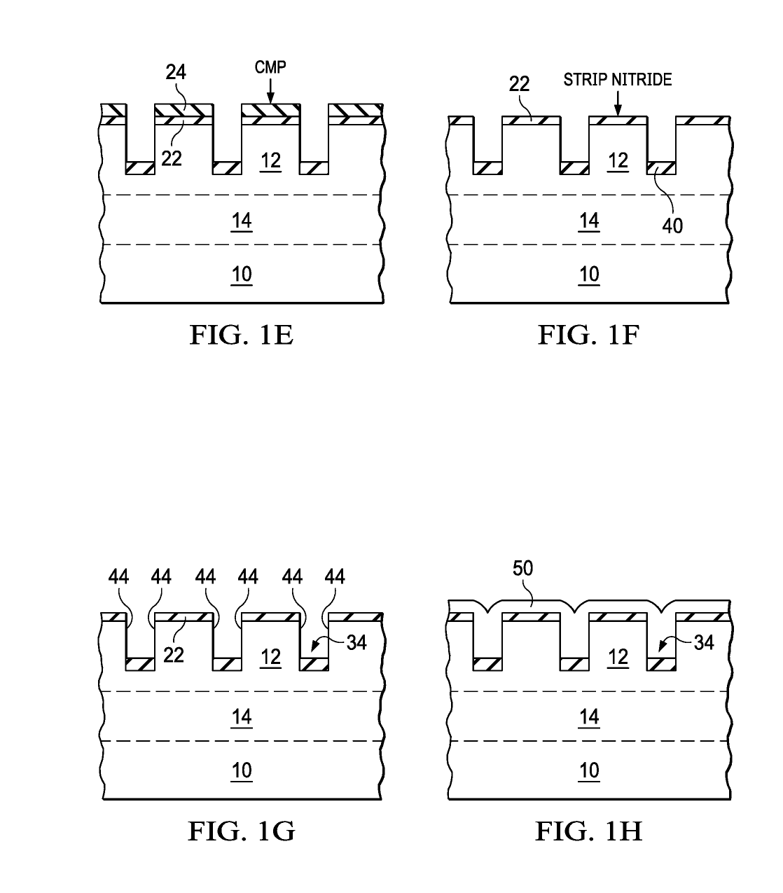

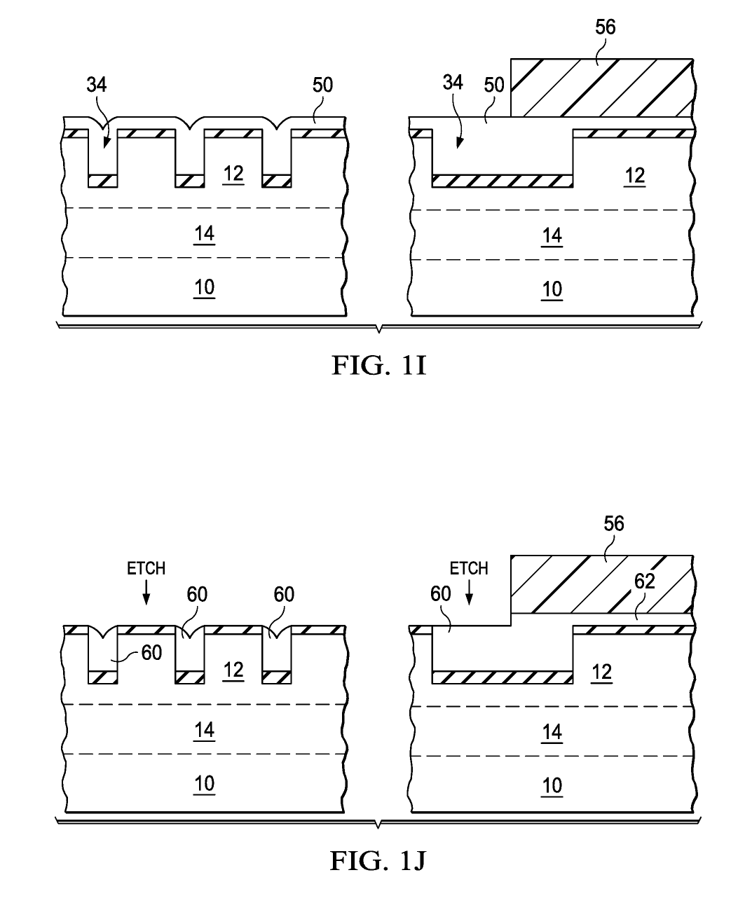

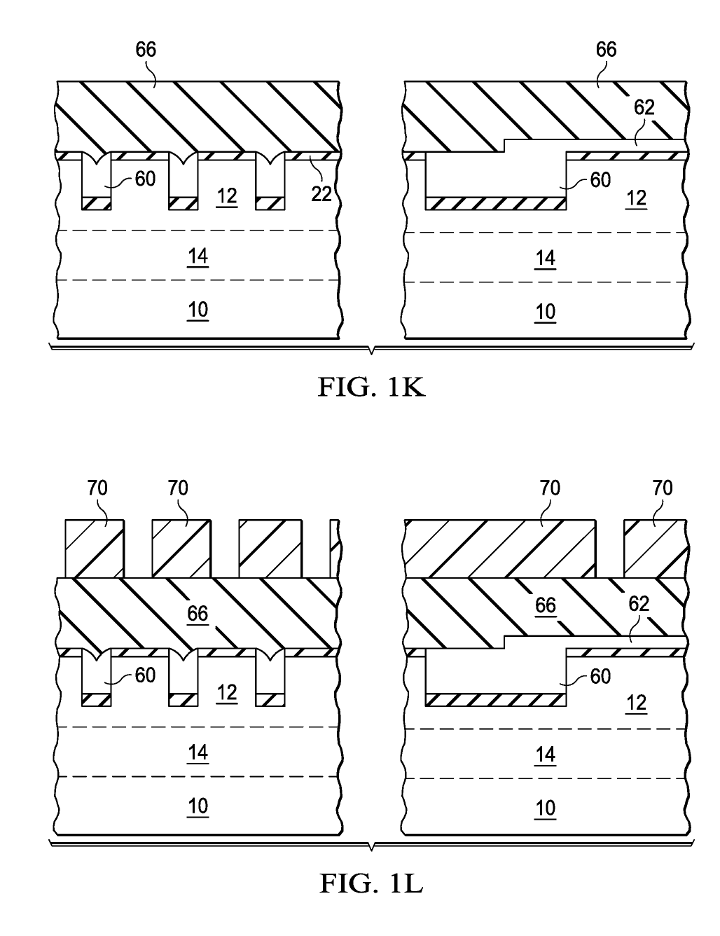

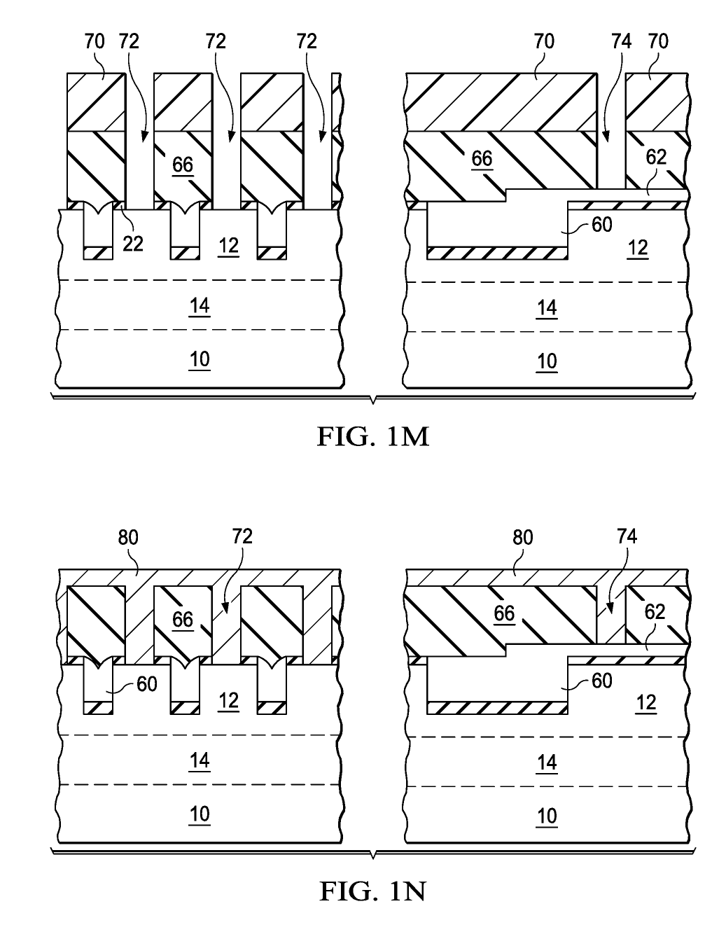

### DETAILED DESCRIPTION

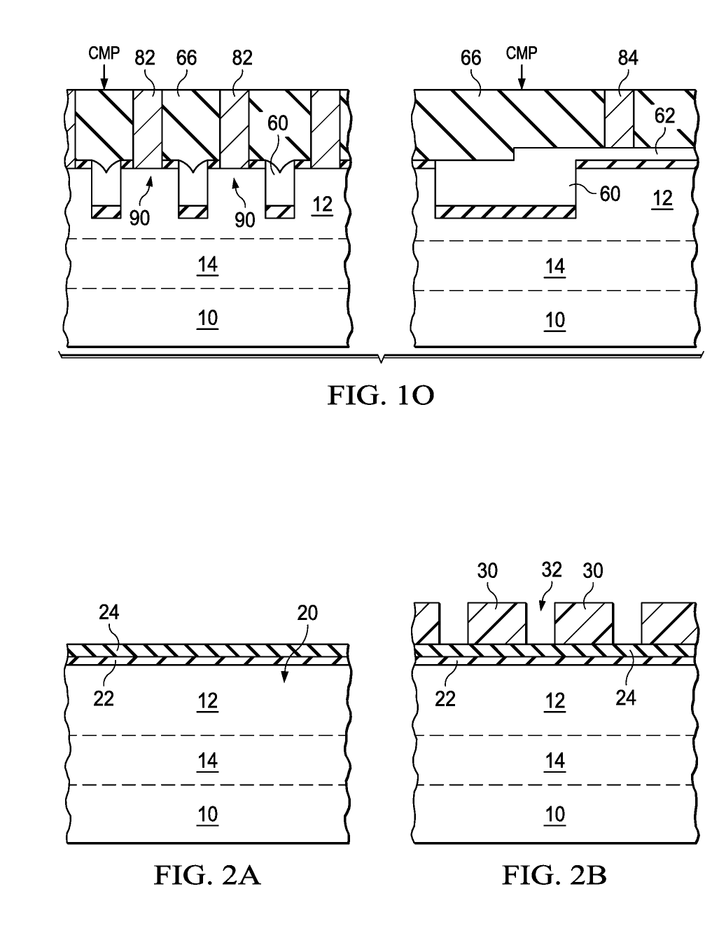

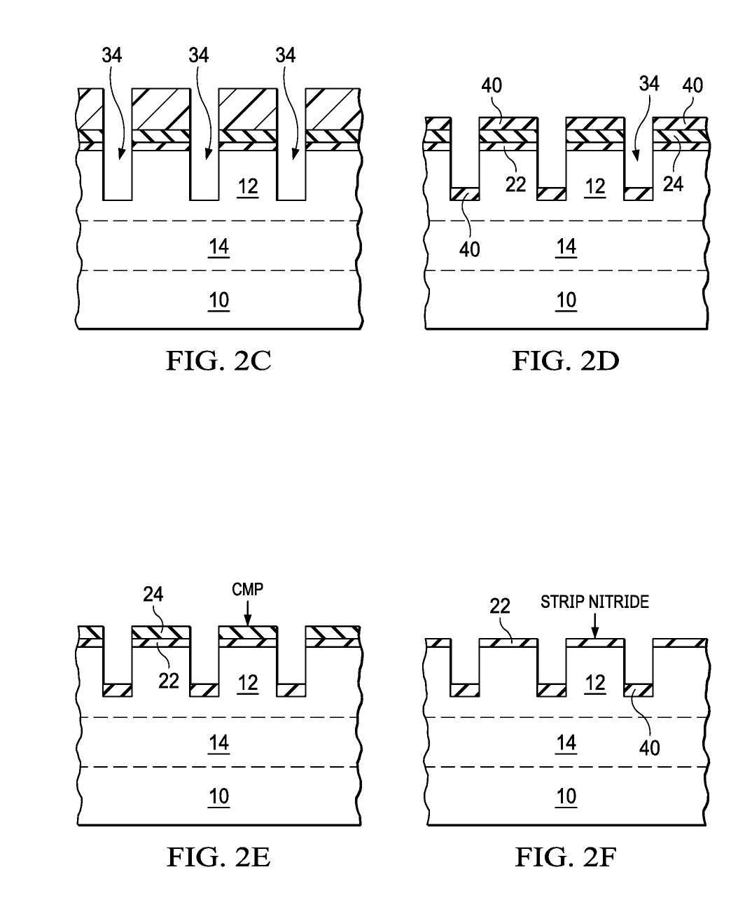

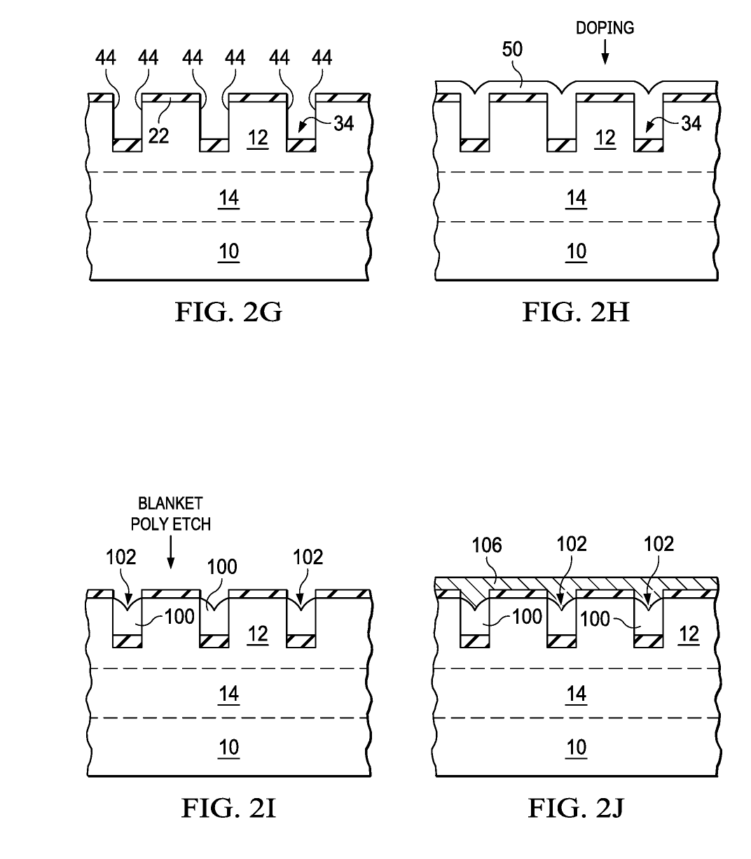

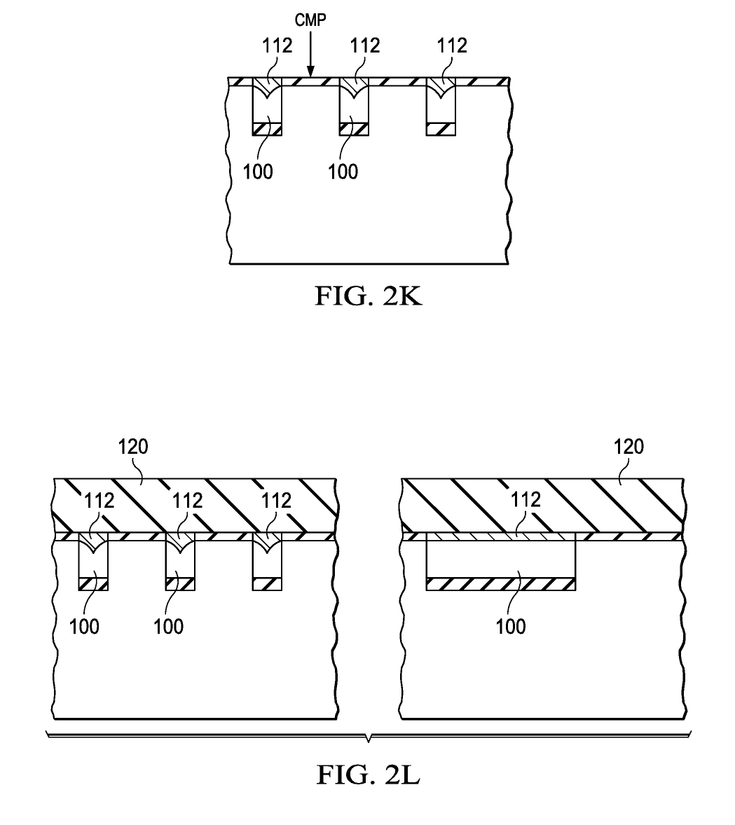

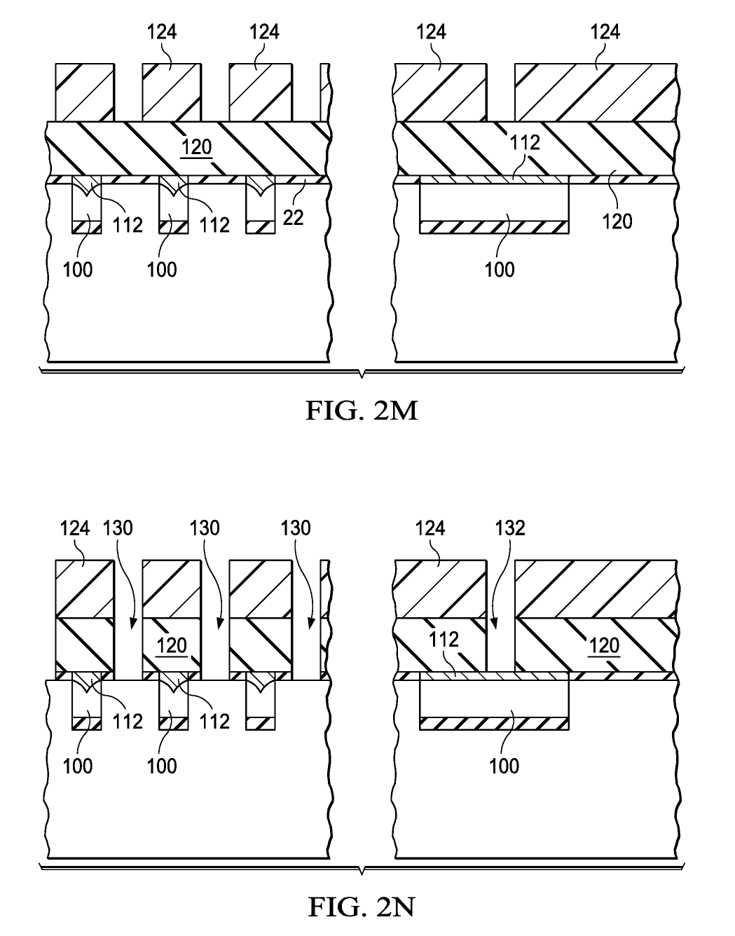

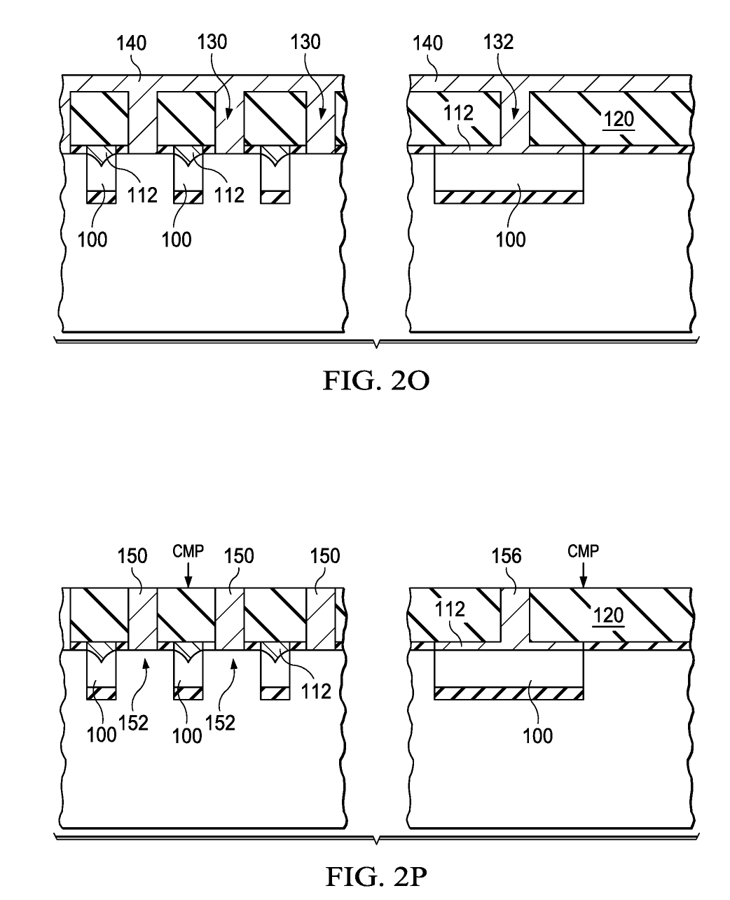

FIGS. 2A-2P illustrate an example method for forming an integrated circuit (IC) structure including multiple trench FET structures, including steps for forming poly gate contacts and a lateral gate coupling element or “strap” conductively connecting each poly gate to a respective gate contact, according to one embodiment of the present invention.

FIGS. 2A-2C show an example technique for forming a plurality of poly gate trenches. As shown in FIG. 2A, a lightly-doped epitaxy (EPI) layer 12 may be formed over a highly-doped bulk silicon substrate 10, and a transition region 14 may form between the EPI layer 12 and bulk substrate 10. The transition region 14 may define a transition from the more lightly doped EPI layer 12 to the more heavily doped bulk substrate region 10. The more lightly doped region may be light enough to survive a breakdown field. The resistance of this region may have consequences for operation of the FET because this area is typically not a pure metal.

Body and source regions 20 may be formed in the EPI 12 by suitable dopant implants, as known in the art. An oxide or insulation layer 22 may be formed, e.g., grown, on the EPI layer 12. In some embodiments, e.g., wherein a thick oxide is deposited in the bottom of the (later-formed) poly gate trenches, as discussed below with reference to FIG. 2D, a nitride layer 24 may be deposited over the oxide layer 22. The nitride layer 24 may be provided to act as a CMP stop for a CMP to remove oxide deposited outside the poly gate trenches.

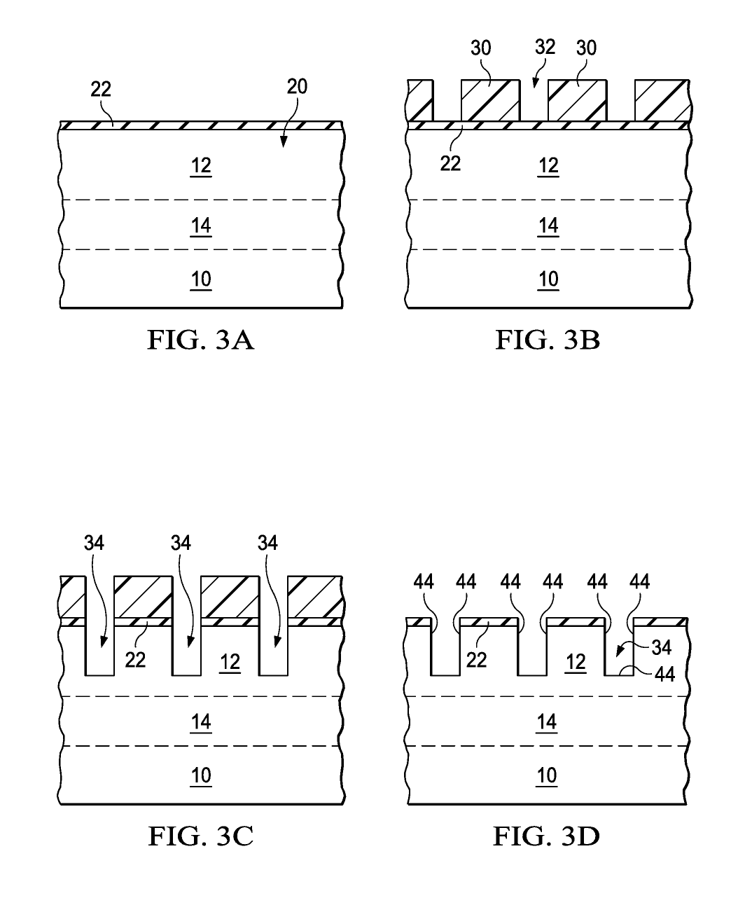

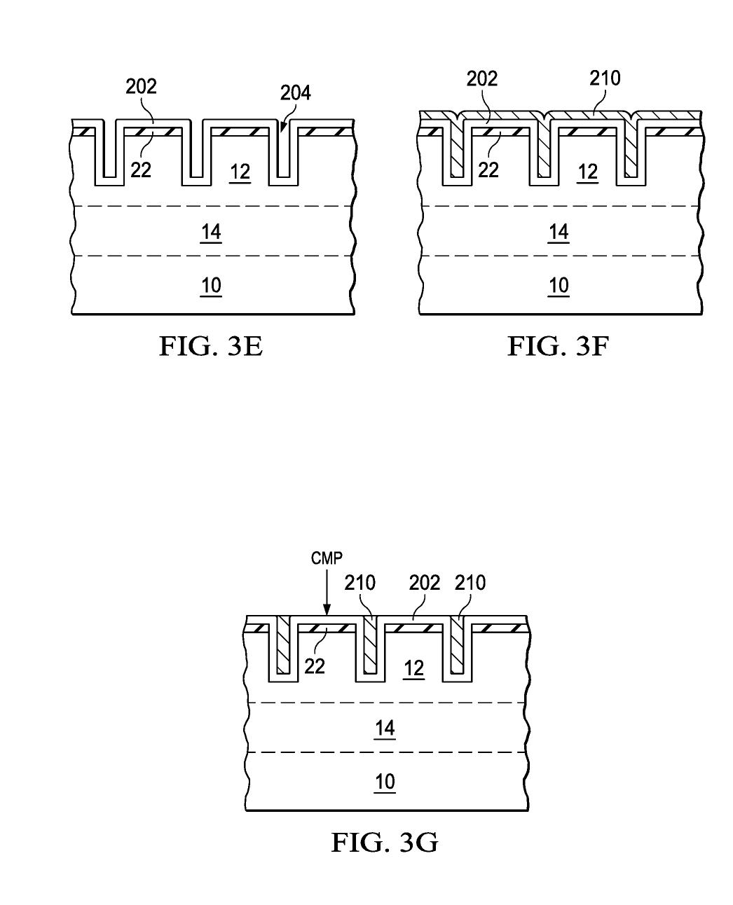

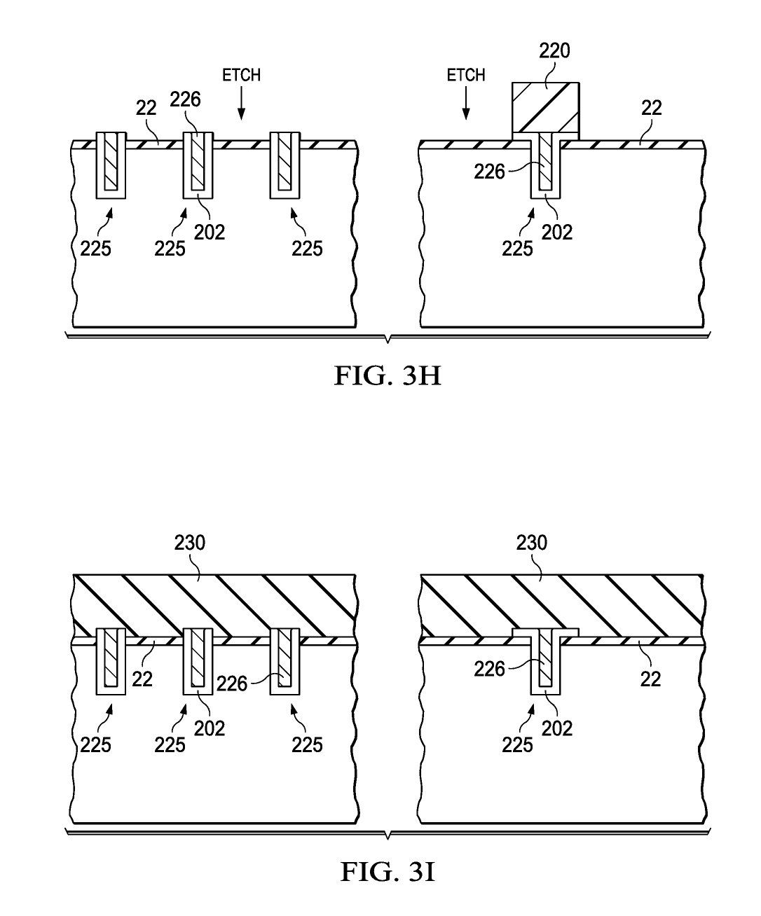

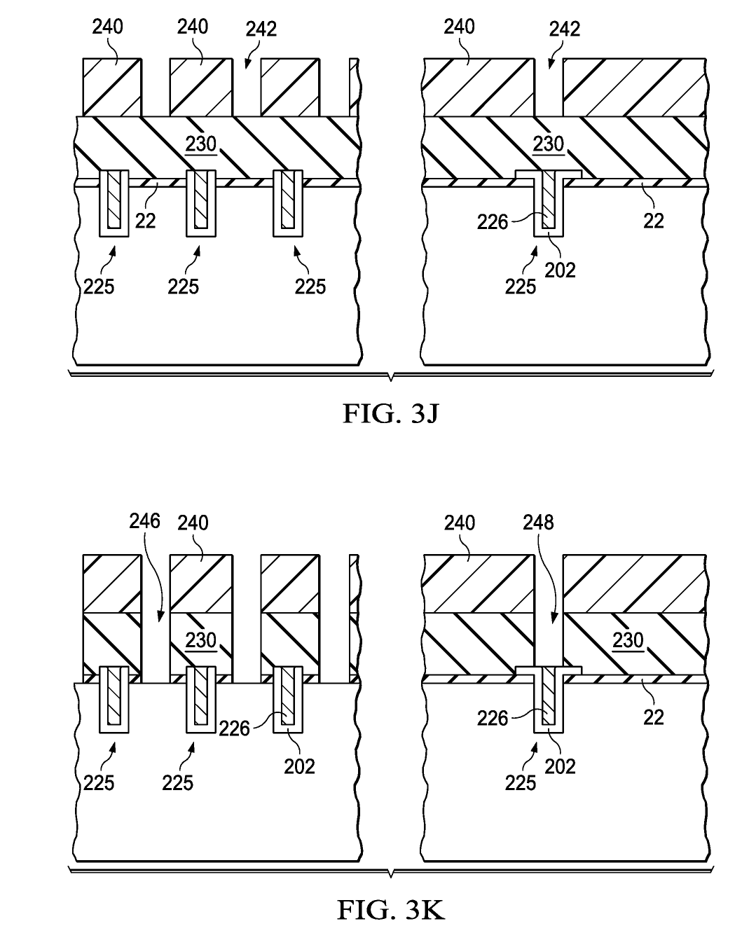

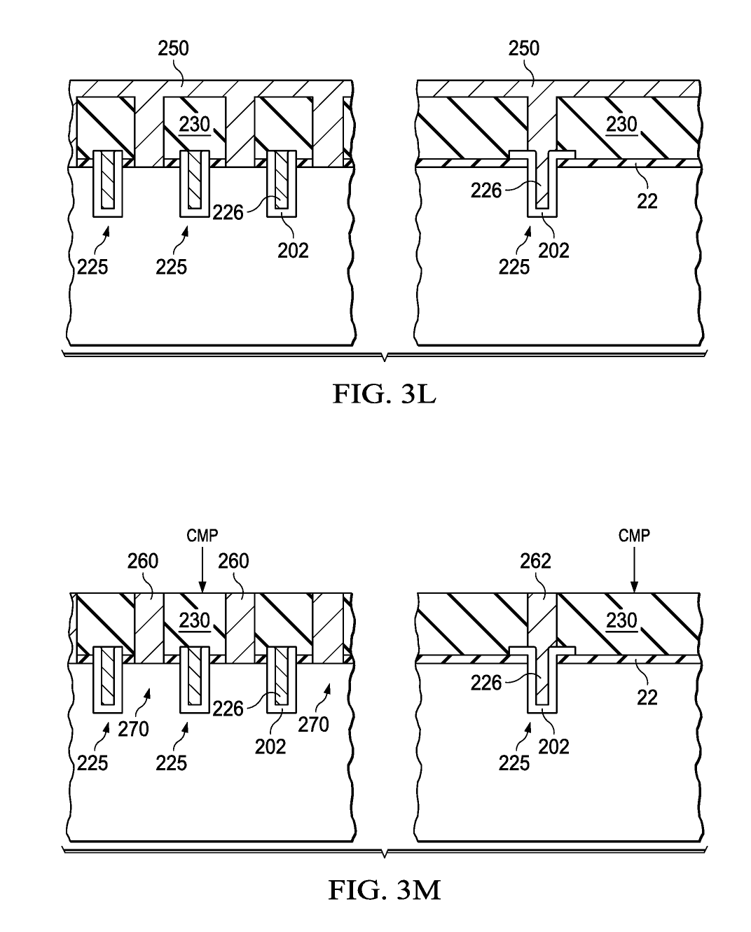

In other embodiments, e.g., where a thick oxide is not deposited in the bottom of the poly gate trenches, the nitride layer 24 may be omitted and a thicker oxide or insulation layer 22 may be used. (An example of this technique in which a thick oxide is not deposited in the bottom of the poly gate trenches, and nitride layer 24 is thus omitted, is embodiment shown in FIGS. 3A-3M discussed below.)

As shown in FIG. 2B, a mask 30 (e.g., photoresist) may be formed and patterned to define trenches 32 in the mask 30.

As shown in FIG. 2C, at least one etch may be performed through the mask trenches 32 to remove portions of the nitride layer 24, oxide layer 22, and EPI region 12, to define a plurality of poly gate trenches 34.

As shown in FIG. 2D, the mask 30 may be removed (e.g., stripped), and an oxide 40 may be deposited over the structure.

As shown in FIG. 2E, a chemical mechanical planarization (CMP) process may be performed to remove the oxide 40 deposited on the nitride layer 24. The nitride layer 24 may act as a stop for the CMP process.

As shown in FIG. 2F, nitride layer 24 may be removed, e.g., stripped.

As shown in FIG. 2G, a gate oxide 44 may be grown on the exposed sidewall surfaces in the poly gate trenches 34.

As shown in FIG. 2H, a poly layer 50 may be deposited over the structure and extending into the poly gate trenches 34. The poly layer 50 may be doped, e.g., as known in the art.

As shown in FIG. 2I, a blanket poly etch may be performed to remove upper portions of the deposited poly layer 50, and thereby define a discrete poly gate 100 in each respective poly gate trench 34. The poly etch may be extended to etch a depression or recess 102 in the top of each poly gate 100 within each respective poly gate trench 34, as shown in FIG. 2I. This recess 102 may be formed to subsequently accept a respective lateral gate coupling element (e.g., “strap”) 112, as discussed below.

As shown in FIG. 2J, tungsten or other suitable metal or electrically conductive material 106 (e.g., having a higher electrical conductivity than the gate poly material) may be deposited over the structure, and extending into the etched recess 102 in the top of each poly gate 100.

As shown in FIG. 2K, a CMP process may be performed to remove upper portions of the deposited conductive material (e.g., tungsten) 106, and thereby define a lateral gate coupling element (e.g., “strap”) 112 over each respective poly gate 110.

Each of FIGS. 2L through 2P includes (a) an example first cross-sectional view (left side) corresponding with a first region of the device structure where no top-side gate contact is formed, e.g., at a laterally interior area of the structure, and (b) an example second cross-sectional view (right side) corresponding with a second region of the device structure where a top-side gate contact is formed, e.g., at or near a perimeter or lateral edge of the structure or at any other location selected for top-side gate contact. In one example embodiment, the example second cross-sectional view shown in the right side of each FIG. 2L-2P may represent a 90 degree rotated view of the example left-side view, e.g., a cross-section taken through one of the poly gate trenches 34. In another example embodiment, the example second cross-sectional view shown in the right side of each FIG. 2L-2P may represent a co-planar or parallel plane view as the example left-side, e.g., at a different location in the device (e.g., at a perimeter or edge region of the device).

As shown in FIG. 2L (lefts and right side views), an oxide layer 120 may be deposited over the structure.

As shown in FIG. 2M, a photomask 124 may be formed over the oxide layer 120 and patterned to define openings for forming source contact trenches (left side view) and poly gate contact trenches (right side view).

As shown in FIG. 2N (left and right side views), at least one etch may be performed through the patterned openings in the photomask 124 and through the underlying oxide layer(s) (including oxide layer 22) to form (a) source contact trenches 130 that expose areas of the top surface of the EPI layer 12 (left side view), and (b) poly gate contact trenches 132 that expose a top surface of respective lateral gate coupling element 112, e.g., tungsten “strap” (right side view).

As shown in FIG. 2O, tungsten or other metal or conductive material 140 may be deposited over the structure and extending into the source contact trenches 130 (left side view) and poly gate contact trenches 132 (right side view), e.g., using a tungsten plug process.

As shown in FIG. 2P, a CMP process may be performed to remove upper portions of the deposited tungsten, and thereby define (a) a plurality of discrete source contacts 150, each contacting a doped source region 152 in the EPI 12 (left side view), and (b) a plurality of poly gate contacts 156, each contacting a respective lateral gate coupling element 112, e.g., tungsten “strap” (right side view).

Thus, each poly gate 100 may be electrically coupled to a respective gate contact 156 by a lateral gate coupling element (e.g., “strap”) 112. In some embodiments, each lateral gate coupling element 112 may be formed from a different material than the respective poly gate 100. For example, as discussed above, each lateral gate coupling element 112 may be formed from a metal, e.g., tungsten, or other electrically conductive material. Each lateral gate coupling element 112 may have a higher electrical conductivity than the gate poly material of the poly gate 100 to which the lateral gate coupling element 112 is coupled. As a result, the lateral gate coupling elements 112 as disclosed herein may provide a reduced gate resistance for a trench FET, as compared with conventional FET designs that use poly material to connect the poly gate to a gate contact. For example, typical poly resistance may be about 80-100 ohms/sq, whereas tungsten has a resistance of about 10 ohms/sq.

FIGS. 3A-3M illustrate another example method for forming an integrated circuit (IC) structure including multiple trench FET structures, including steps for forming poly gate contacts and a lateral gate coupling element or “strap” conductively connecting each poly gate to a respective gate contact, according to one embodiment of the present invention. The example method shown in FIGS. 3A-3M may produce a lateral gate coupling elements/straps that extend further down in to the respective poly gate trenches than the lateral gate coupling elements/straps produced by the method shown in FIGS. 2A-2P.

FIGS. 3A-3C show an example technique for forming a plurality of poly gate trenches. As shown in FIG. 3A, a lightly-doped epitaxy (EPI) layer 12 may be formed over a highly-doped bulk silicon substrate 10, and a transition region 14 may form between the EPI layer 12 and bulk substrate 10. The transition region 14 may define a transition from the more lightly doped EPI layer 12 to the more heavily doped bulk substrate region 10. The more lightly doped region may be light enough to survive a breakdown field. The resistance of this region may have consequences for operation of the FET because this area is typically not a pure metal.

Body and source regions 20 may be formed in the EPI 12 by suitable dopant implants, as known in the art. An oxide or insulation layer 22 may be formed, e.g., grown, on the EPI layer 12. In an alternative embodiment, e.g., wherein a thick oxide is deposited in the bottom of the (later-formed) poly gate trenches, as discussed above with respect to embodiment shown in FIGS. 2A-2P, a nitride layer 24 may be deposited over the oxide layer 22, which may act as a CMP stop during a CMP performed after depositing the thick oxide extending into the poly gate trenches.

As shown in FIG. 3B, a mask 30 (e.g., photoresist) may be formed and patterned to define trenches 32 in the mask 30.

As shown in FIG. 3C, at least one etch may be performed through the mask trenches 32 to remove portions of the oxide layer 22 and EPI region 12, to define a plurality of poly gate trenches 34.

As shown in FIG. 3D, the mask 30 may be removed (e.g., stripped), and a gate oxide 44 may be grown on the exposed sidewall and bottom surfaces of the poly gate trenches 34.

As shown in FIG. 3E, a thin conformal poly layer 202 may be deposited over the structure and extending into the poly gate trenches 34. The thickness of the thin poly layer 202 may be selected such that a trench opening 204 is defined in each trench 34. The poly layer 202 may be doped, e.g., as known in the art.

As shown in FIG. 3F, tungsten or other suitable metal or electrically conductive material 210 (e.g., having a higher electrical conductivity than the gate poly material) may be deposited over the structure, and extending down into the trench openings 204 within each poly gate trench 34.

As shown in FIG. 3G, a CMP process may be performed to remove upper portions of the deposited conductive material (e.g., tungsten) 210.

Each of FIGS. 3H through 3M includes (a) an example first cross-sectional view (left side) corresponding with a first region of the device structure where no top-side gate contact is formed, e.g., at a laterally interior area of the structure, and (b) an example second cross-sectional view (right side) corresponding with a second region of the device structure where a top-side gate contact is formed, e.g., at or near a perimeter or lateral edge of the structure or at any other location selected for top-side gate contact. In one example embodiment, the example second cross-sectional view shown in the right side of each FIG. 3H-3M may represent a 90 degree rotated view of the example left-side view, e.g., a cross-section taken through one of the poly gate trenches 34. In another example embodiment, the example second cross-sectional view shown in the right side of each FIG. 3H-3M may represent a co-planar or parallel plane view as the example left-side, e.g., at a different location in the device (e.g., at a perimeter or edge region of the device).

As shown in FIG. 3H, a resist is deposited and patterned over the area where the top-side gate contact is to be formed. An etch may then be performed, to remove upper portions of the deposited poly layer 202, and thereby define a discrete poly gate 225 in each respective poly gate trench 34. The oxide layer 22 and/or the conductive material (e.g., tungsten) 210 in each trench 34 may act as an etch stop.

As shown, each poly gate 225 may include a poly liner 202 within the respective trench 34 and a tungsten (or other conductive material) insert 210 extending down into the trench. The tungsten insert in each trench 225 may define a lateral gate coupling element (e.g., “strap”) 226 to provide an improved conductive path from the poly material 202 to a respective gate contact (which may be formed as discussed below), thereby providing an improved conductive path between source regions adjacent each poly gate 225 and the respective gate contacts.

As shown, each lateral gate coupling element 226 may extend substantially down into the respective trench 34. For example, in some embodiments, each lateral gate coupling element 226 may extend down to a depth of at least 25% of the depth of the respective trench 34. In some embodiments, each lateral gate coupling element 226 may extend down to a depth of at least 50% of the depth of the respective trench 34. In particular embodiments, each lateral gate coupling element 226 may extend down to a depth of at least 75% of the depth of the respective trench 34.

As shown in FIG. 3I (lefts and right side views), an oxide layer 230 may be deposited over the structure.

As shown in FIG. 3J, a photomask 240 may be formed over the oxide layer 230 and patterned to define openings 242 for forming source contact trenches (left side view) and poly gate contact trenches (right side view).

As shown in FIG. 3K (left and right side views), at least one etch may be performed through the patterned openings 242 in the photomask 240 and through the underlying oxide layer(s) 230 and 22 to form (a) source contact trenches 246 that expose areas of the top surface of the EPI layer 12 (left side view), and (b) poly gate contact trenches 248 that expose a top surface of respective lateral gate coupling element 226, e.g., tungsten “strap” (right side view).

As shown in FIG. 3L, tungsten or other metal or conductive material 250 may be deposited over the structure and extending into the source contact trenches 246 (left side view) and poly gate contact trenches 248 (right side view), e.g., using a tungsten plug process.

As shown in FIG. 3M, a CMP process may be performed to remove upper portions of the deposited tungsten, and thereby define (a) a plurality of discrete source contacts 260, each contacting a doped source region 270 in the EPI 12 (left side view), and (b) a plurality of poly gate contacts 262, each contacting a respective lateral gate coupling element 226, e.g., tungsten “strap” (right side view).

Thus, each poly gate 225 may be electrically coupled to a respective gate contact 262 by a lateral gate coupling element (e.g., “strap”) 226. In some embodiments, each lateral gate coupling element 226 may be formed from a different material than the respective poly material 202. For example, as discussed above, each lateral gate coupling element 226 may be formed from a metal, e.g., tungsten, or other electrically conductive material. Each lateral gate coupling element 226 may have a higher electrical conductivity than the gate poly material 202 of the poly gate 225. As a result, the lateral gate coupling elements 226 as disclosed herein may provide a reduced gate resistance for a trench FET, as compared with conventional FET designs that use poly material to connect the poly gate to a gate contact. For example, typical poly resistance may be about 80-100 ohms/sq, whereas tungsten has a resistance of about 10 ohms/sq.

It should be noted that the reference labels for EPI layer 12, transition region 14, and bulk silicon substrate 10 are omitted from FIGS. 2K-2P and FIGS. 3H-3M for illustrative purposes only, and that such regions are in fact present in the structures shown in each figure.

1. An integrated circuit (IC) device, comprising:
a plurality of trench-type field-effect transistors (trench FETs), each trench FET comprising:
a poly gate trench formed in an epitaxy region;
a poly gate formed in the poly gate trench;
a front-side poly gate contact; and
a lateral gate coupling element extending over or adjacent at least one surface of the poly gate formed in the trench and electrically connecting the poly gate to the front-side poly gate contact.

2. The device of claim 1, wherein each trench FET further comprises:
a doped source region formed in the epitaxy region; and
a front-side source contact coupled to the doped source region.

3. The device of claim 1, wherein the lateral gate coupling element is formed from a different material than the poly gate.

4. The device of claim 1, wherein the lateral gate coupling element has a higher electrical conductivity than the poly gate.

5. The device of claim 1, wherein the lateral gate coupling element comprises a metal.

6. The device of claim 1, wherein the lateral gate coupling element comprises tungsten.

7. The device of claim 1, wherein the lateral gate coupling element is at least partially located in the poly gate trench.

8. The device of claim 1, wherein the lateral gate coupling element extends down to at least 25% of a depth of the poly gate trench.

9. The device of claim 1, wherein the lateral gate coupling element extends down to at least 50% of a depth of the poly gate trench.

10. The device of claim 1, wherein the lateral gate coupling element extends down to at least 75% of a depth of the poly gate trench.

11. The device of claim 1, wherein the lateral gate coupling element extends over a top surface of the poly gate formed in the trench.

12. The device of claim 1, wherein the lateral gate coupling element extends down into a cavity defined by poly material deposited in the trench.

13. A field-effect transistor (FET), comprising:
a poly gate trench formed in an epitaxy region;
a poly gate formed in the poly gate trench;
a front-side poly gate contact; and
a lateral gate coupling element extending over or adjacent at least one surface of the poly gate formed in the trench and electrically connecting the poly gate to the front-side poly gate contact.

14. The FET of claim 8, further comprising:
a doped source region formed in the epitaxy region; and
a front-side source contact coupled to the doped source region.

15. The FET of claim 8, wherein the lateral gate coupling element is formed from a different material than the poly gate.

16. The FET of claim 8, wherein the lateral gate coupling element has a higher electrical conductivity than the poly gate.

17. The FET of claim 8, wherein the lateral gate coupling element comprises tungsten.

18. The FET of claim 8, wherein the lateral gate coupling element is at least partially located in the poly gate trench.

19. An electronic device, comprising:
an integrated circuit (IC) device, comprising:
a plurality of trench-type field-effect transistors (trench FETs), each trench FET comprising:
a poly gate trench formed in an epitaxy region;
a poly gate formed in the poly gate trench;
a front-side poly gate contact; and
a lateral gate coupling element extending over or adjacent at least one surface of the poly gate formed in the trench and electrically connecting the poly gate to the front-side poly gate contact.

20. A method of forming an integrated circuit (IC) structure including a plurality of trench-type field-effect transistors (trench FETs), the method comprising:
forming a poly gate trench in an epitaxy region;
forming a poly gate in the poly gate trench;
forming a lateral gate coupling element extending over or adjacent, and coupled to, at least one surface of the poly gate;
forming a front-side poly gate contact coupled to the lateral gate coupling element; and
wherein the lateral gate coupling element forms an electrical connection between the poly gate and the front-side poly gate contact.

21. The method of claim 16, wherein the lateral gate coupling element is formed from a different material than the poly gate.

22. The method of claim 16, wherein the lateral gate coupling element has a higher electrical conductivity than the poly gate.

23. The method of claim 16, wherein the lateral gate coupling element comprises tungsten.

24. The method of claim 16, wherein the lateral gate coupling element is at least partially located in the poly gate trench.

25. The method of claim 16, comprising:
etching a top portion of the poly gate in the poly gate trench to define a recess in the poly gate; and
forming the lateral gate coupling element such that the lateral gate coupling element extends at least partially into the etched recess in the poly gate.
